(19) United States
(12) Patent Application Publication
(10) Pub. No.: US 2024/0302169 A1
(43) Pub. Date: Sep. 12, 2024

(54) INERTIAL MEASUREMENT UNIT (IMU) WITH BLENDING OF OUTPUTS FROM AN ARRAY OF MICRO-ELECTROMECHANICAL SYSTEM (MEMS) SENSORS

(71) Applicant: Honeywell International Inc., Charlotte, NC (US)

(72) Inventors: Christopher J. Mauer, Roseville, MN (US); Shuang Li, Shanghai (CN); Zhizhen Shen, Shanghai (CN); Jingwei Li, Pizhou City (CN)

(73) Assignee: Honeywell International Inc., Charlotte, NC (US)

(21) Appl. No.: 18/179,609

(22) Filed: Mar. 7, 2023

(51) Int. Cl. G01C 21/16; B81B 7/02; G01C 21/18

(52) U.S. Cl. CPC G01C 21/188; B81B 7/02; G01C 21/18; B81B 2201/0235; B81B 2201/0242; B81B 2207/05; G01C 21/166

(57) ABSTRACT

An inertial measurement unit (IMU). The IMU includes: a plurality of micro-electromechanical system (MEMS) sensors, each having an output; a memory for storing calibration coefficients separately for each of the plurality of MEMS sensors, blending weights for each of the plurality of MEMS sensors, and data blending instructions for blending the outputs of the plurality of MEMS sensors; and a processor, coupled to the memory and the plurality of MEMS sensors, configured to execute the data blending instructions to apply the calibration coefficients separately to each of the plurality of MEMS sensors and the blending weights to the outputs of the plurality of MEMS sensors to create a blended output for the IMU; wherein the blending weights are calculated based on a plurality of test parameters for the plurality of MEMS sensors using at least one of a harmonic and a geometric mean of the plurality of test parameters.

### BACKGROUND

An inertial measurement unit (IMU) is an electronic device that measures and reports data on, for example, acceleration, angular rate and orientation of an associated body using a combination of gyroscopes, accelerometers and sometimes magnetometers. IMUs are used in a variety of applications such as inertial navigation systems to provide navigation and control functions for aircraft, missiles, ships, submarines and satellites. Many conventional IMUs are large, expensive and require high power for proper operation.

Lower-grade IMUs have been developed using micro-electromechanical system (MEMS) gyroscopes and accelerometers. These MEMS-based IMUs are smaller, cheaper and operate on less power than conventional IMUs. Such IMUs with MEMS sensors are used extensively in applications that have lower accuracy requirements. For example, IMUs with MEMS sensors are used in most smart phones and tablets to track and report the orientation of the device. Fitness trackers and other wearables include IMUs with MEMS sensors to measure motion such as running or walking.

IMUs with MEMS sensors (gyroscopes and accelerometers) conventionally have had a limited role in Global Navigation Satellite System/Inertial Navigation System (GNSS/INS) integrated navigation due to high measurement noise and unstable performance parameters of MEMS sensors. Thus, conventional GNSS/INS integrated navigation systems have been denied access to the low size, weight and power (SWAP) commonly associated with the use of MEMS sensors.

Thus, there is a need in the art for developing an IMU that leverages the low SWAP associated with MEMS sensors while providing the high-performance characteristics associated with conventional IMUs used in navigation systems.

### SUMMARY

In one embodiment, an inertial measurement unit (IMU) is provided. The IMU includes: a plurality of micro-electromechanical system (MEMS) sensors, each of the plurality of MEMS sensor having an output; a memory for storing calibration coefficients separately for each of the plurality of MEMS sensors, blending weights for each of the plurality of MEMS sensors, and data blending instructions for blending the outputs of the plurality of MEMS sensors; and a processor, coupled to the memory and the plurality of MEMS sensors, configured to execute the data blending instructions to apply the calibration coefficients separately to each of the plurality of MEMS sensors and to apply the blending weights to the outputs of the plurality of MEMS sensors to create a blended output for the inertial measurement unit; wherein the blending weights are calculated based on a plurality of test parameters for the plurality of MEMS sensors using at least one of a harmonic mean and a geometric mean of the plurality of test parameters.

### BRIEF DESCRIPTION OF THE DRAWINGS

Embodiments of the present invention can be more easily understood and further advantages and uses thereof more readily apparent, when considered in view of the description of the preferred embodiments and the following figures in which:

FIG. 1 is block diagram of one embodiment of an inertial measurement unit (IMU) that includes an array of micro-electromechanical system (MEMS) sensors.

FIG. 2 is flow chart that illustrates one embodiment of a method for manufacturing the inertial measurement unit of FIG. 1.

FIG. 3 is a flow chart of one embodiment of a method for calculating blending weights for an inertial measurement unit that blends the outputs of an array of MEMS sensors.

FIG. 4 is a flow chart of another embodiment of a method for calculating blending weights for an inertial measurement unit that blends the outputs of an array of MEMS sensors.

FIG. 5 is data flow diagram of one embodiment of an inertial measurement unit that blends the outputs of an array of MEMS sensors.

FIG. 6 is a data flow diagram of another embodiment of an inertial measurement unit that blends the outputs of an array of MEMS sensors.

In accordance with common practice, the various described features are not drawn to scale but are drawn to emphasize features relevant to the present invention. Reference characters denote like elements throughout figures and text.

### DETAILED DESCRIPTION

In the following detailed description, reference is made to the accompanying drawings that form a part hereof, and in which is shown by way of specific illustrative embodiments in which the invention may be practiced. These embodiments are described in sufficient detail to enable those skilled in the art to practice the invention, and it is to be understood that other embodiments may be utilized and that logical, mechanical and electrical changes may be made without departing from the scope of the present invention. The following detailed description is, therefore, not to be taken in a limiting sense.

Embodiments of the present invention provide an inertial measurement unit (IMU) with low size, weight and power (SWAP) specifications due to the use of an array of low grade (consumer) micro-electromechanical system (MEMS) sensors. It has been found that embodiments of the present invention with an array of N independent MEMS sensors, each with the same measurement error level, can reduce measurement errors of the IMU by approximately the square root of N times by properly fusing or blending the outputs of the N independent MEMS sensors. For example, when an IMU is configured with an array of 12 MEMS sensors, the IMU can produce an output that is 3-4 times more precise than any of the MEMS sensors in the array operating alone as explained in more detail below.

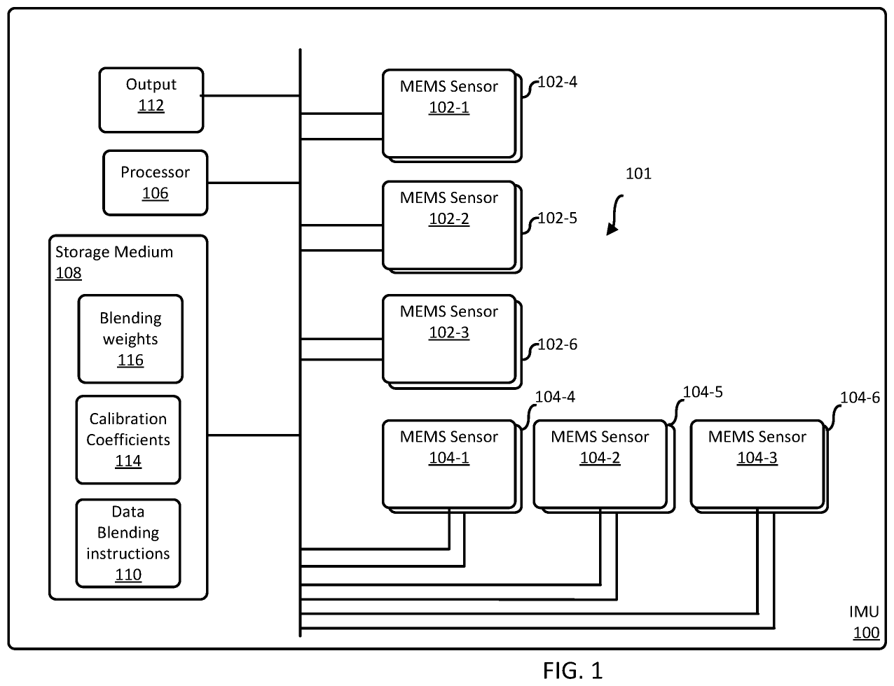

FIG. 1 is block diagram of one embodiment of an inertial measurement unit (IMU) 100 that includes a plurality of micro-electromechanical system (MEMS) sensors that are coupled together to form array 101. IMU 100 includes processor 106 and storage medium 108. Processor 106 may be implemented using one or more processors, a field programmable gate array (FPGA), an application specific integrated circuit (ASIC), a controller or other circuit used to execute instructions in an electronic circuit. Storage medium 108 stores program instructions including data blending instructions 110 that, when executed by processor 106, enables blending of the outputs of array 101 of MEMS sensors to produce a blended output at output 112 of IMU 100. Storage medium 108 can include any available storage media (or computer readable medium) that can be accessed by a general purpose or special purpose computer or processor, or any programmable logic device. Suitable computer readable media may include storage or memory media such as semiconductor, magnetic, and/or optical media, and may be embodied as a program product comprising instructions stored in non-transitory computer readable media, such as random access memory (RAM), read-only memory (ROM), non-volatile RAM, electrically-erasable programmable ROM, flash memory, or other storage media. Storage medium 108 may also include one or more databases to store acquired data. Storage medium 108 can be implemented by appropriate circuitry.

Additionally, storage medium 108 also include data to be used in the blending of the outputs of array 101. This data includes calibration coefficients 114 and blending weights 116. Calibration coefficients 114 are stored separately for each of the MEMS sensors in array 101 and include, in one non-limiting example, coefficients that correct or compensate for issues related to, for example, bias, scale factor and cross-axis coupling, and temperature. The blending weights 116, discussed in more detail below, include separate blending weights for each axis of each MEMS sensor in array 101. In one embodiment, array 101 of MEMS sensors used in IMU 100 each include, for example, a three-axis gyroscope and a three-axis accelerometer (with X, Y and Z axes for each).

Further, in the embodiment shown in FIG. 1, array 101 includes 12 MEMS sensors. In this example, the MEMS sensors of array 101 are divided into two groups. The first group includes 6 MEMS sensors 102-1 to 102-6 and the second group includes 6 MEMS sensors 104-1 to 104-6. In this arrangement, the first group of MEMS sensors 102-1 to 102-6 are disposed at a 90-degree angle in the horizontal plane of IMU 100 to the second group of MEMS sensors 104-1 to 104-6. In other embodiments, the MEMS sensors in array 101 are oriented in any appropriate number of groups with any appropriate angular orientation, each group including a subset of the MEMS sensors. Additionally, in other embodiments, all of the MEMS sensors in the array 101 are all oriented in a single group and orientation.

In operation, MEMS sensors 102-1 to 102-6 and MEMS sensors 104-1 to 104-6 provide traditional IMU outputs to processor 106. Processor 106 executes the data blending instructions 110 to create a blended output for IMU 100 at output 112 using the data from array 101, the calibration coefficients 114 and the blending weights 116. Processor 106 separately calibrates each of the MEMS sensors in array 101 using the calibration coefficients 114, e.g., calibration coefficients for bias correction, scale factor and cross-axis coupling, and temperature compensation. As mentioned above, in one embodiment, a separate set of calibration coefficients is applied to each of the MEMS sensors in array 101. Additionally, processor 106 blends the calibrated outputs of the MEMS sensors in array 101 using the data blending instructions 110. These data blending instructions 110, when run on processor 106, cause processor 106 to apply the blending weights 116 to the outputs of each of the calibrated MEMS sensors in array 101. In other words, processor 106 scales the outputs of each of the calibrated MEMS sensors in array 101 using a blending weight calculated for that MEMS sensor based on parameters from static test results for each of the MEMS sensors. Processor 106 then combines the weighted outputs of the MEMS sensors in array 101 to provide the output 112 of IMU 100. Advantageously, output 112 is more precise than the output of any one of the MEMS sensors in array 101 by a factor of 3 to 4 by using the blending weights and the calibration coefficients with an array 101 of 12 MEMS sensors.

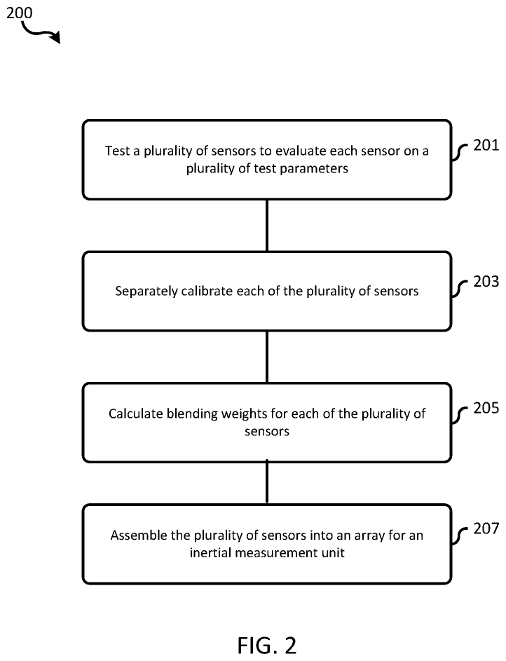

FIG. 2 is flow chart that illustrates one embodiment of a method, indicated generally at 200, for manufacturing the inertial measurement unit 100 of FIG. 1. The method begins at block 201 by testing each of the MEMS sensors of array 101. Each of the MEMS sensors 102-1 to 102-6 and MEMS sensors 104-1 to 104-6 are independently tested for a plurality of test parameters. During the tests, data is collected for each test parameter for each MEMS sensor in the array 101. Additionally, for each MEMS sensor in the array 101, data for each test parameter is collected for the gyroscopes and, separately, for the accelerometers of the MEMS sensor. In one embodiment, the test parameters include measurements related to:
1. Bias Repeatability (power on/off N times, N>6)
2. Static Data for Allan Variance (bias instability and angle random walk)
3. Static Data for Output Noise (Standard deviation)

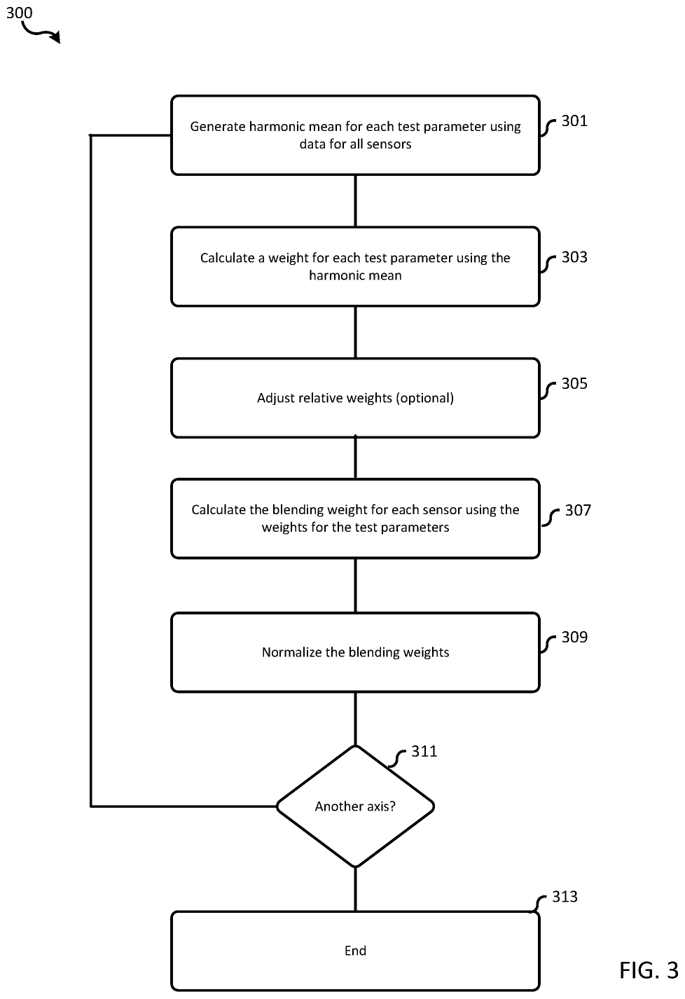

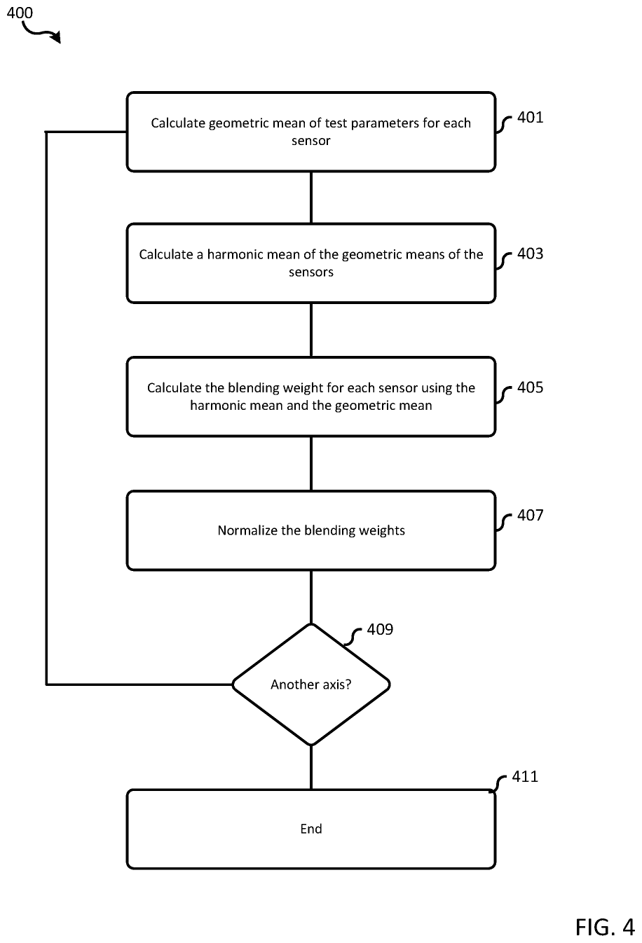

At block 203, each of the MEMS sensors in array 101 is calibrated to determine calibration coefficients for to correct for bias, scale factor and cross-axis coupling, and temperature. Further, method 200 also calculates blending weights for each of the MEMS sensors in array 101 at block 205. In one embodiment, the blending weights for each of the MEMS sensors in array 101 are identical. This is referred to as the “averaging method” in which each sensor is given a weight equal to the reciprocal of the number of MEMS sensors in array 101. FIGS. 3 and 4, described in more detail below, provide alternative embodiments for calculating the blending weights for the MEMS sensors of array 101 based on the plurality of test parameters for MEMS sensors in array 101 using at least one of a harmonic mean and a geometric mean of the plurality of test parameters. At block 207, the MEMS sensors are assembled into array 101 of an inertial measurement unit 100 and the calibration coefficients 114 and the blending weights 116 are stored in storage medium 108.

FIG. 3 is a flow chart of one embodiment of a method, indicated generally at 300, for calculating blending weights for an inertial measurement unit that blends the outputs of an array of MEMS sensors, such as IMU 100 of FIG. 1. As an initial matter, a blending weight is calculated separately for each axis of a MEMS sensor. This includes six axes in total: X, Y, and Z axes for the accelerometer and X, Y, and Z axes for the gyroscope of each MEMS sensor. Additionally, method 300 uses test parameter values for each axis of each MEMS sensor. The test parameters, in one embodiment, include: bias instability, angle random walk, bias repeatability, and noise. In other embodiments, other test parameters are used that enable appropriate weights to be assigned to each MEMS sensor based on the relative quality of the output of that MEMS sensor. In general, the higher the weight assigned to a MEMS sensor indicates the better the performance of the MEMS sensor based on the test parameters that were used to evaluate the MEMS sensors.

At block 301, method 300 begins with the data for one axis, e.g., the X axis of the gyroscopes of the MEMS sensors in array 101. Method 300 generates a harmonic mean for each test parameter using the data from all of the MEMS sensors in array 101. This produces a harmonic mean for each parameter across all of the MEMS sensors in array 101. At block 303, method 300 calculates a weight for each test parameter using the harmonic mean. For example, for each MEMS sensor, the value of each parameter is divided by the harmonic mean for that parameter across all of the MEMS sensors to produce the weight for the test parameter. In some embodiments, this weight is further divided by the number of MEMS sensors in the array 101.

Advantageously, in some embodiments, method 300 includes an option to selectively adjust the relative weights calculated at block 303 to emphasis one or more of the test parameters. For example, in a specific application, it may be desired to improve bias instability in the performance of the IMU. In that case, the weights calculated at block 303 for each test parameter may be selectively adjusted to emphasize bias instability by increasing the relative impact of the data derived for bias instability relative to the other test parameters at optional block 305. In one embodiment, this is accomplished by assigning a relative adjustment value, e.g., a value between 0 and 1, to each parameter and multiplying the calculated weight by the relative adjustment value. In one example, if the relative adjustment value for bias instability is assigned a value of 1 and the relative adjustment value for the other test parameters are each assigned to zero, the calculated weight for bias instability will be the only non-zero weight and will this control the relative weights of all of the MEMS sensors.

Method 300 calculates the blending weight for the particular axis under consideration by combining the weights calculated for each of the test parameters at block 307. Finally, method 300 normalizes the calculated blending weight to 1. This means that the blending weights for this axis for all of the MEMS sensors are scaled proportionately so that the sum of the blending weights for all of the MEMS sensors is equal to 1.

At block 311, method 300 determines if any of the axes of the MEMS sensors have not been calculated. If so, method 300 returns to block 301 and calculates blending weights for an additional axis of the MEMS sensors. Method 300 repeats this process until block 311 determines that there are no further axes of the MEMS sensors in need of a blending weight and method 300 ends at block 313.

FIG. 4 is a flow chart of another embodiment of a method, indicated at 400, for calculating blending weights for an inertial measurement unit that blends the outputs of an array of MEMS sensors. As with method 300 of FIG. 3, method 400 also calculates a blending weight for each axis of a MEMS sensor using test parameter values for each axis of each MEMS sensor. The test parameters, in one embodiment, include: bias instability, angle random walk, bias repeatability, and noise.

Method 400 begins at block 401 and calculates a geometric mean of all of the test parameters for each of the MEMS sensors in the IMU for one axis, e.g., the X axis of the gyroscopes of the MEMS sensors in array 101. This results in each sensor having a geometric mean based on all the test parameters for that sensor. At block 403, method 400 calculates a harmonic mean from the geometric means for each MEMS sensor of array 101. At block 405, method 400 calculates the blending weights for each MEMS sensor based on the harmonic mean and the geometric mean. In one embodiment, this involves dividing the geometric mean for each sensor by the harmonic mean of all sensors. At block 407, the blending weights are normalized to 1. This means that the blending weights for this axis for all of the MEMS sensors are scaled proportionately so that the sum of all of the blending weights for all of the MEMS sensors is equal to 1.

At block 409, method 400 determines if any of the axes have not been calculated. If so, method 400 returns to block 401 and calculates blending weights for an additional axis. Method 400 repeats this process until block 409 determines that there are no further axes of the MEMS sensors in need of a blending weight and method 400 ends at block 411.

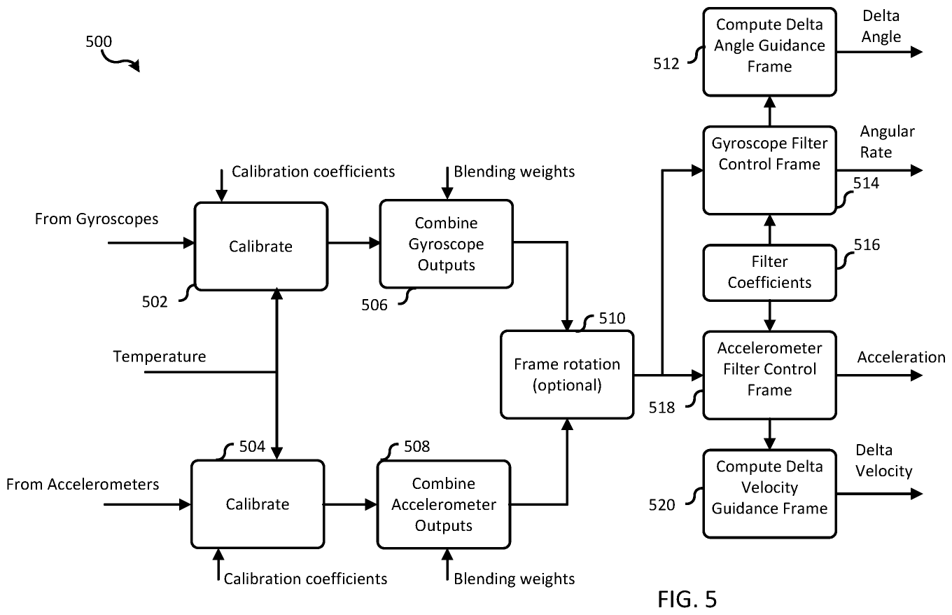

FIG. 5 is data flow diagram, indicated at 500, that illustrates one embodiment of a data flow for an inertial measurement unit (IMU) that blends the outputs of an array of MEMS sensors using blending weights calculated from a number of test parameters for each of the MEMS sensors, e.g., bias instability, angle random walk, bias repeatability, and noise. In some embodiments, each of the MEMS sensors include a three-axis gyroscope and a three-axis accelerometer and the blending weights are calculated using one or more of the techniques described in detail above.

The IMU processes data from the MEMS sensors to produce output data typically associated with an IMU. To do this, IMU receives raw data from the three-axis gyroscopes of the MEMS sensors at block 502 and raw data from the three-axis accelerometers of the MEMS sensors at block 504. The data from the gyroscopes and accelerometers are processed separately.

In the gyroscope path, the raw data is calibrated at block 502 using calibration coefficients and temperature data that was separately derived for each of the MEMS sensors. The calibration process corrects for bias, scale factor and cross-axis coupling, and temperature. Additionally, the outputs of the gyroscopes are blended or combined at block 506 using the blending weights. As noted previously, a separate blending weight is applied to the data for each axis of each gyroscope of each MEMS sensor.

Similarly, in the accelerometer path, the raw data is calibrated at block 504 using calibration coefficients and temperature data that was separately derived for each of the MEMS sensors. The calibration process corrects for bias, scale factor and cross-axis coupling, and temperature. Additionally, the outputs of the accelerometers are blended or combined at block 508 using the blending weights. As noted previously, a separate blending weight is applied to the data for each axis of each accelerometer of each MEMS sensor.

Once the outputs of the array of MEMS sensors are calibrated and blended, the IMU performs, for example, traditional processing of raw IMU data to produce the outputs of the IMU. For example, frame rotation is optionally performed at 510 for the blended outputs of the gyroscopes and accelerometers. Additionally, delta angle (block 512), angular rate (block 514), acceleration (block 518) and delta velocity (block 520) are calculated from the blended outputs of the MEMS sensors using, for example, traditional functions and filter coefficients 516.

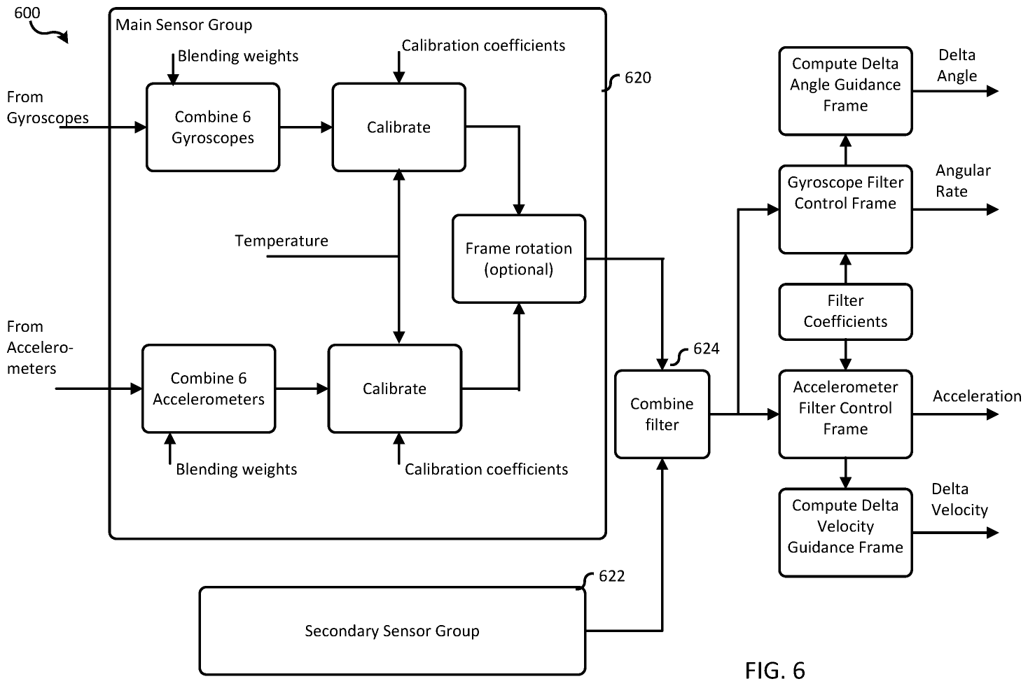

FIG. 6 is a data flow diagram, indicated generally at 600, of another embodiment of an inertial measurement unit that blends the outputs of an array of MEMS sensors. The data flow of this embodiment is similar to the data flow described above with respect to FIG. 5. In FIG. 6, however, the MEMS sensors are divided into two groups: a main sensor group 620 and a secondary sensor group 622. The raw data from the MEMS sensors in the main sensor group 620 is processed in the same manner described above with blending weights and calibration coefficients with respect to FIG. 5. The raw data from the MEMS sensors in the secondary sensor group 622 is also similarly processed. The outputs of the main sensor group 620 and the secondary sensor group 622 are combined in block 624. The balance of the data flow is the same as described above with respect to FIG. 5.

### Example Embodiments

Although specific embodiments have been illustrated and described herein, it will be appreciated by those of ordinary skill in the art that any arrangement, which is calculated to achieve the same purpose, may be substituted for the specific embodiment shown. This application is intended to cover any adaptations or variations of the present invention. Therefore, it is manifestly intended that this invention be limited only by the claims and the equivalents thereof.

Example 1 includes an inertial measurement unit comprising: a plurality of micro-electromechanical system (MEMS) sensors, each of the plurality of MEMS sensor having an output; a memory for storing calibration coefficients separately for each of the plurality of MEMS sensors, blending weights for each of the plurality of MEMS sensors, and data blending instructions for blending the outputs of the plurality of MEMS sensors; and a processor, coupled to the memory and the plurality of MEMS sensors, configured to execute the data blending instructions to apply the calibration coefficients separately to each of the plurality of MEMS sensors and to apply the blending weights to the outputs of the plurality of MEMS sensors to create a blended output for the inertial measurement unit; wherein the blending weights are calculated based on a plurality of test parameters for the plurality of MEMS sensors using at least one of a harmonic mean and a geometric mean of the plurality of test parameters.

Example 2 includes the inertial measurement unit of example 1, wherein the plurality of

MEMS sensor comprise a first group of MEMS sensors that is oriented at an angle to at least one other group of MEMS sensors.

Example 3 includes the inertial measurement unit of any of examples 1 and 2, wherein the plurality of MEMS sensors each comprise a three-axis gyroscope and a three-axis accelerometer.

Example 4 includes the inertial measurement unit of example 3, wherein the blending weights for each of the plurality of MEMS sensors are calculated separately for each axis of the three-axis gyroscope and the three-axis accelerometer.

Example 5 includes the inertial measurement unit of example 4, wherein the blending weights are calculated based on the plurality of test parameters comprising: bias instability, angle random walk, bias repeatability, and noise.

Example 6 includes the inertial measurement unit of any of examples 4 and 5, wherein the blending weights for each of the plurality of MEMS sensors are calculated based on a plurality of test parameters for the plurality of MEMS sensors using a harmonic mean for each of the plurality of test parameters.

Example 7 includes the inertial measurement unit of example 6, wherein blending weights for each of the plurality of MEMS sensors are calculated based on a factor that is configurable to selectively adjust an impact of each test parameter on the blending weights.

Example 8 includes the inertial measurement unit of example 4, wherein the blending weights for each of the plurality of MEMS sensors are calculated based on a geometric mean of a plurality of test parameters for each of the plurality of sensors, and a harmonic mean of the geometric mean of the plurality of test parameters for each of the plurality of MEMS sensors.

Example 9 includes a method including: testing a plurality of independent MEMS sensors to evaluate each of the plurality of MEMS sensors based on a plurality of test parameters; separately calibrating each of the plurality of independent MEMS sensors; calculating blending weights for each of the plurality of independent MEMS sensors based on at least one of a harmonic mean and a geometric mean of the plurality of test parameters; and assembling the plurality of independent MEMS sensors into an array for an inertial measurement unit, wherein an output of the inertial measurement unit is configured to be calculated from outputs of the plurality of independent MEMS sensors and the blending weights.

Example 10 includes the method of example 9, wherein testing the plurality of independent MEMS sensors comprises testing the plurality of independent MEMS sensors for bias instability, angle random walk, bias repeatability, and noise.

Example 11 includes the method of any of examples 9 and 10, wherein separately calibrating each of the plurality of independent MEMS sensors comprises determining calibration coefficients for bias correction, scale factor and cross-axis coupling, and temperature.

Example 12 includes the method of any of examples 9 to 11, wherein testing a plurality of independent MEMS sensors comprises testing a first group of MEMS sensors that is oriented at an angle to at least one other group of MEMS sensors.

Example 13 includes the method of any of examples 9 to 12, wherein calculating the blending weights for each of the plurality of MEMS sensors comprises calculating the blending weights based on the plurality of test parameters for the plurality of MEMS sensors using a harmonic mean for each of the plurality of test parameters.

Example 14 includes the method of any of examples 9 to 13, wherein calculating the blending weights for each of the plurality of MEMS sensors comprises calculating the blending weights based on a geometric mean of the plurality of test parameters for each of the plurality of sensors, and a harmonic mean of the geometric mean of the plurality of test parameters for each of the plurality of MEMS sensors.

Example 15 includes a program product comprising a non-transitory computer-readable medium on which program instructions configured to be executed by at least one processor are embodied, wherein when executed by the at least one processor, the program instructions cause the at least one processor to perform the method comprising: receiving a plurality of test parameters for a plurality of independent MEMS sensors, the test parameters created based on testing of the plurality of MEMS sensors; calculating blending weights for each of the plurality of independent MEMS sensors based on at least one of a harmonic mean and a geometric mean of the plurality of test parameters; and providing the blending weights to an inertial measurement unit that includes the plurality of independent MEMS sensors coupled together to form an array, wherein an output of the inertial measurement unit is configured to be calculated from outputs of the plurality of independent MEMS sensors and the blending weights.

Example 16 includes the program product of example 15, wherein receiving a plurality of test parameters comprises receiving a plurality of test parameters including bias instability, angle random walk, bias repeatability, and noise for the plurality of independent MEMS sensors.

Example 17 includes the program product of any of examples 15 and 16, wherein calculating the blending weights for each of the plurality of independent MEMS sensors comprises calculating the blending weights separately for each axis of a three-axis gyroscope and a three-axis accelerometer.

Example 18 includes the program product of any of examples 15 to 17, wherein receiving a plurality of parameters for a plurality of independent MEMS sensors comprises receiving a plurality of test parameters for a first group of MEMS sensors that is oriented at an angle to at least one other group of MEMS sensors.

Example 19 includes the program product of any of examples 15 to 18, wherein calculating the blending weights for each of the plurality of independent MEMS sensors comprises calculating the blending weights based on the plurality of test parameters for the plurality of independent MEMS sensors using a harmonic mean for each of the plurality of test parameters.

Example 20 includes the program product of any of examples 15 to 19, wherein calculating the blending weights for each of the plurality of independent MEMS sensors comprises calculating the blending weights based on a geometric mean of the plurality of test parameters for each of the plurality of independent MEMS sensors, and a harmonic mean of the geometric mean of the plurality of test parameters for each of the plurality of independent MEMS sensors.

What is claimed is:

1. An inertial measurement unit comprising:
a plurality of micro-electromechanical system (MEMS) sensors, each of the plurality of MEMS sensor having an output;
a memory for storing calibration coefficients separately for each of the plurality of MEMS sensors, blending weights for each of the plurality of MEMS sensors, and data blending instructions for blending the outputs of the plurality of MEMS sensors; and
a processor, coupled to the memory and the plurality of MEMS sensors, configured to execute the data blending instructions to apply the calibration coefficients separately to each of the plurality of MEMS sensors and to apply the blending weights to the outputs of the plurality of MEMS sensors to create a blended output for the inertial measurement unit;
wherein the blending weights are calculated based on a plurality of test parameters for the plurality of MEMS sensors using at least one of a harmonic mean and a geometric mean of the plurality of test parameters.

2. The inertial measurement unit of claim 1, wherein the plurality of MEMS sensor comprise a first group of MEMS sensors that is oriented at an angle to at least one other group of MEMS sensors.

3. The inertial measurement unit of claim 1, wherein the plurality of MEMS sensors each comprise a three-axis gyroscope and a three-axis accelerometer.

4. The inertial measurement unit of claim 3, wherein the blending weights for each of the plurality of MEMS sensors are calculated separately for each axis of the three-axis gyroscope and the three-axis accelerometer.

5. The inertial measurement unit of claim 4, wherein the blending weights are calculated based on the plurality of test parameters comprising: bias instability, angle random walk, bias repeatability, and noise.

6. The inertial measurement unit of claim 4, wherein the blending weights for each of the plurality of MEMS sensors are calculated based on a plurality of test parameters for the plurality of MEMS sensors using a harmonic mean for each of the plurality of test parameters.

7. The inertial measurement unit of claim 6, wherein blending weights for each of the plurality of MEMS sensors are calculated based on a factor that is configurable to selectively adjust an impact of each test parameter on the blending weights.

8. The inertial measurement unit of claim 4, wherein the blending weights for each of the plurality of MEMS sensors are calculated based on a geometric mean of a plurality of test parameters for each of the plurality of sensors, and a harmonic mean of the geometric mean of the plurality of test parameters for each of the plurality of MEMS sensors.

9. A method comprising:
testing a plurality of independent MEMS sensors to evaluate each of the plurality of MEMS sensors based on a plurality of test parameters;
separately calibrating each of the plurality of independent MEMS sensors;
calculating blending weights for each of the plurality of independent MEMS sensors based on at least one of a harmonic mean and a geometric mean of the plurality of test parameters; and
assembling the plurality of independent MEMS sensors into an array for an inertial measurement unit, wherein an output of the inertial measurement unit is configured to be calculated from outputs of the plurality of independent MEMS sensors and the blending weights.

10. The method of claim 9, wherein testing the plurality of independent MEMS sensors comprises testing the plurality of independent MEMS sensors for bias instability, angle random walk, bias repeatability, and noise.

11. The method of claim 9, wherein separately calibrating each of the plurality of independent MEMS sensors comprises determining calibration coefficients for bias correction, scale factor and cross-axis coupling, and temperature.

12. The method of claim 9, wherein testing a plurality of independent MEMS sensors comprises testing a first group of MEMS sensors that is oriented at an angle to at least one other group of MEMS sensors.

13. The method of claim 9, wherein calculating the blending weights for each of the plurality of MEMS sensors comprises calculating the blending weights based on the plurality of test parameters for the plurality of MEMS sensors using a harmonic mean for each of the plurality of test parameters.

14. The method of claim 9, wherein calculating the blending weights for each of the plurality of MEMS sensors comprises calculating the blending weights based on a geometric mean of the plurality of test parameters for each of the plurality of sensors, and a harmonic mean of the geometric mean of the plurality of test parameters for each of the plurality of MEMS sensors.

15. A program product comprising a non-transitory computer-readable medium on which program instructions configured to be executed by at least one processor are embodied, wherein when executed by the at least one processor, the program instructions cause the at least one processor to perform the method comprising:
receiving a plurality of test parameters for a plurality of independent MEMS sensors, the test parameters created based on testing of the plurality of MEMS sensors;
calculating blending weights for each of the plurality of independent MEMS sensors based on at least one of a harmonic mean and a geometric mean of the plurality of test parameters; and
providing the blending weights to an inertial measurement unit that includes the plurality of independent MEMS sensors coupled together to form an array, wherein an output of the inertial measurement unit is configured to be calculated from outputs of the plurality of independent MEMS sensors and the blending weights.

16. The program product of claim 15, wherein receiving a plurality of test parameters comprises receiving a plurality of test parameters including bias instability, angle random walk, bias repeatability, and noise for the plurality of independent MEMS sensors.

17. The program product of claim 15, wherein calculating the blending weights for each of the plurality of independent MEMS sensors comprises calculating the blending weights separately for each axis of a three-axis gyroscope and a three-axis accelerometer.

18. The program product of claim 15, wherein receiving a plurality of parameters for a plurality of independent MEMS sensors comprises receiving a plurality of test parameters for a first group of MEMS sensors that is oriented at an angle to at least one other group of MEMS sensors.

19. The program product of claim 15, wherein calculating the blending weights for each of the plurality of independent MEMS sensors comprises calculating the blending weights based on the plurality of test parameters for the plurality of independent MEMS sensors using a harmonic mean for each of the plurality of test parameters.

20. The program product of claim 15, wherein calculating the blending weights for each of the plurality of independent MEMS sensors comprises calculating the blending weights based on a geometric mean of the plurality of test parameters for each of the plurality of independent MEMS sensors, and a harmonic mean of the geometric mean of the plurality of test parameters for each of the plurality of independent MEMS sensors.
